(19) United States
(12) Patent Application Publication
(10) Pub. No.: US 2015/0263011 A1
(43) Pub. Date: Sep. 17, 2015

(54) SEMICONDUCTOR DEVICE AND METHOD FOR MANUFACTURING THE SAME

(71) Applicant: SK hynix Inc., Gyeonggi-do (KR)

(72) Inventor: Young Ok HONG, Gyeonggi-do (KR)

(21) Appl. No.: 14/480,131

(22) Filed: Sep. 8, 2014

(30) Foreign Application Priority Data
Mar. 12, 2014 (KR) 10-2014-0029008

(51) Int. Cl. H01L 27/112; H01L 27/115

(52) U.S. Cl. CPC H01L 27/11286; H01L 27/11582

(57) ABSTRACT

A semiconductor device and a method of manufacturing the same, wherein the semiconductor device includes a memory string; a first metal pattern for a source line formed under the memory string; a second metal pattern for a peripheral circuit interconnection horizontally spaced apart from the first metal pattern; and peripheral circuit transistors connected to the second metal pattern.

### CROSS-REFERENCE TO RELATED APPLICATION

The present application claims priority to Korean patent application number 10-2014-0029008, filed on Mar. 12, 2014, the entire disclosure of which is incorporated herein in its entirety by reference.

### BACKGROUND

1. Field of Invention

Various exemplary embodiments of the present invention relate to a semiconductor device and a method of manufacturing the same, and more particularly, to a semiconductor memory device that includes 3-dimensional memory string, and a method for manufacturing the same.

2. Description of Related Art

A semiconductor device includes a memory device capable of storing data. The memory device includes a memory cell array area on which memory cell strings are disposed, and a peripheral circuit area on which a peripheral circuit is disposed to drive the memory cell strings.

A proposal for achieving high integration of a semiconductor device includes a memory device having memory cells, which constitute the memory cell strings, arranged in 3-dimensions. Recently, various techniques of improving the operation characteristics of the 3-dimensional memory device, and further improving the degree of integration thereof, have been developed.

### SUMMARY

Various embodiments of the present invention are directed to a semiconductor device including a 3-dimensional memory string and a method of manufacturing the same.

One embodiment of the present invention provides a semiconductor device including: a memory string; a first metal pattern for a source line formed under the memory string; a second metal pattern for a peripheral circuit interconnection horizontally spaced apart from the first metal pattern; and peripheral circuit transistors connected to the second metal pattern.

Another embodiment of the present invention provides a semiconductor device including: peripheral circuit transistors formed on a substrate; metal patterns disposed over the peripheral circuit transistors in a same level; and a memory string formed over the metal patterns, wherein the metal patterns include peripheral circuit interconnections connected to the peripheral circuit transistors and a source line connected to the memory string.

Yet another embodiment of the present invention provides a semiconductor device including: a bit line; an interconnection line and a source line disposed under the bit line, wherein a distance between the interconnection line and the bit line is the same as a distance between the source line and the bit line; a memory string connected between the bit line and the source line; a page buffer circuit disposed under the interconnection line; a first contact plug connected between the page buffer circuit and the interconnection line; and a second contact plug connected between the interconnection line and the bit line.

Yet another embodiment of the present invention provides a method of manufacturing a semiconductor device including: forming transistors on a substrate; forming at least one lower interlayer insulating layer to cover the transistors; forming a metal layer on the lower interlayer insulating layer; forming a first metal pattern for a source line and a second metal pattern for peripheral circuit interconnection by etching the metal layer; and forming a memory string connected to the first metal pattern.

### BRIEF DESCRIPTION OF THE DRAWINGS

The above and other features and advantages of the present invention will become more apparent to those of ordinary skill in the art by describing in detail exemplary embodiments with reference to the attached drawings in which:

FIG. 1 is a cross-sectional view illustrating a semiconductor device according to an embodiment of the present invention;

FIGS. 2A to 2C are cross-sectional views illustrating a method of manufacturing a structure formed under a memory string of a semiconductor device according to an embodiment of the present invention;

FIG. 3 is a perspective view illustrating a method of manufacturing a memory string of a semiconductor device according to an embodiment of the present invention;

FIG. 4 is a block diagram illustrating a memory system according to an embodiment of the present invention; and

FIG. 5 is a block diagram illustrating a computing system according to an embodiment of the present invention.

### DETAILED DESCRIPTION

The present invention will be described more fully hereinafter with reference to the accompanying drawings, in which exemplary embodiments of the invention are shown. This invention may, however, be embodied in different forms and should not be construed as limited to the embodiments set forth herein.

Rather, these embodiments are provided so that this disclosure will be thorough and complete, and will fully convey the scope of the present invention to those skilled in the art. In the drawings, a thicknesses and a distance of components are exaggerated compared to an actual physical thickness and interval for convenience of illustration. In the following description, detailed explanation of known related functions and constitutions may be omitted to avoid unnecessarily obscuring the subject manner of the present invention. Like reference numerals refer to like elements throughout the specification and drawings.

Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exist or are added.

It should be readily understood that the meaning of “on” and “over” in the present disclosure should be interpreted in the broadest manner so that “on” means not only “directly on” but also “on” something with an intermediate feature(s) or a layer(s) therebetween, and that “over” means not only directly on top but also on top of something with an intermediate feature(s) or a layer(s) therebetween.

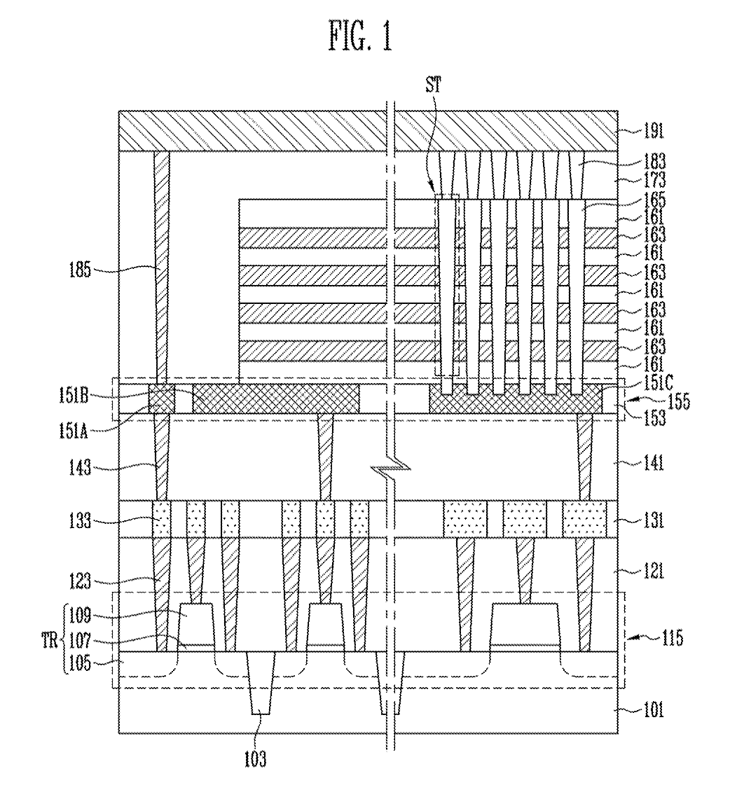

FIG. 1 is a cross-sectional view illustrating a semiconductor device according to an embodiment of the present invention.

As illustrated in FIG. 1, a semiconductor device according to an embodiment of the present invention includes metal patterns 151A, 151B, and 151C horizontally spaced apart from one another on a substrate 101, a memory string ST disposed over the metal patterns 151A, 151B, and 151C, a bit line 191 connected on the memory string ST, and a peripheral circuit 115 disposed under the metal patterns 151A, 151B, and 151C and configured to control an operation of the memory string ST.

The metal patterns 151A, 151B, and 151C are disposed over the substrate 101 in the same level 155. In other words, the metal patterns 151A, 151B, and 151C are spaced apart from the bit line 191 by the same distance. An inter-metal insulating layer 153 may be formed between the metal patterns 151A, 151B, and 151C. The metal patterns 151A, 151B and 151C are simultaneously patterned and are formed of the same materiel. The metal patterns 151A, 151B, and 151C include peripheral circuit interconnections 151A and 151B, and a source line 151C. The peripheral circuit interconnections 151A and 151B are connected to the peripheral circuit 115. The source line 151C is connected to the memory string ST, and may be divided into units of memory blocks or into units of the memory strings ST. The source line 151C may be connected to a plurality of memory blocks.

According to an embodiment of the present invention, the metal patterns 151A, 151B, and 151C including the source line 151C, are formed of a metal having a lower resistance than silicon, such as tungsten or copper. The metal patterns 151A, 151B, and 151C are formed of a silicide having a lower resistance than silicon, such as tungsten silicide. Therefore, a resistance of the source line 151C according to the present invention may be lowered to less than that of a conventional source line formed of an impurity injection area inside a silicon substrate or formed of doped poly-silicon.

Further, according to an embodiment of the present invention, since the source line 151C is formed in the same level 155 as the peripheral circuit interconnections 151A and 151B connected to the peripheral circuit 115, a height of the semiconductor device is not increased due to the source line 151C being formed of a metal.

The memory string ST is connected to the source line 151C and the bit line 191. The memory string ST includes cell interlayer insulating layers 161 and conductive patterns 163, which are alternately stacked on the source line 151C, and a channel layer 165 connected to the source line 151C through the cell interlayer insulating layers 161 and the conductive patterns 163. According to an embodiment of the present invention, since the channel layer 165 is connected to the source line 151C formed of a metal having a low resistance, a cell current flowing along the channel layer 165 may be secured.

At least one layer from the lowermost layer of the conductive patterns 163 may be used as a first select line, at least one layer from the uppermost layer thereof may be used as a second select line, and others may be used as word lines.

The channel layer 165 may be formed in a tube shape to cover an insulating layer that fills in a central area of a through hole along a side all of the through hole passing through the cell interlayer insulating layers 161 and the conductive patterns 163. The channel layer 165 may be formed in a buried shape filling from a surface of the through hole passing through the cell interlayer insulating layers 161 and the conductive patterns 163, to the central area thereof. The channel layer 165 may be formed to have a structure including a tube shape and a buried shape.

Although not shown in this drawing, a multilayered insulating layer (not shown) is interposed between the channel layer 165 and the conductive patterns 163. The multilayered insulating layer may include a tunnel insulating layer (not shown), a data storage layer (not shown), and a blocking, insulating layer (not shown). At least one of the tunnel insulating layer, the data storage layer, and the blocking insulating layer may extend between the channel layer 165 and the cell interlayer insulating layers 161, or between the cell interlayer insulating layers 161 and the conductive patterns 163.

A first select transistor is formed at an intersection of the above-described first select line and the channel layer 165, a second select transistor is formed at an intersection of the second select line and the channel layer 165, and memory cells are formed at intersections of the word lines and the channel layer 165. According to the above-described structure, the memory string ST includes the first select transistor, the memory cells, and the second select transistor, which are connected in series and stacked between the source line 151C and the bit line 191 along the channel layer 165, and is formed to have a 3-dimensional structure.

When an upper interlayer insulating layer 173 is further formed between the memory string ST and the bit line 191, the bit line 191 may be connected to the memory string ST via a drain contact plug 183 passing through the upper interlayer insulating layer 173. The drain contact plug 183 is connected on the channel layer 165 through the upper interlayer insulating layer 173. The bit line 191 may be connected to at least one (for example, a page buffer interconnection 151A) of the peripheral circuit interconnections 151A and 151B. A bit line contact plug 185 may be connected between the bit line 191 and the page buffer interconnection 151. The bit line contact plug 185 may be formed through the upper interlayer insulating layer 173 located between the bit line 191 and the page buffer interconnection 151A.

The peripheral circuit 115 may be configured of transistors TR. The transistors TR may include a page buffer, a row decoder, a column decoder, etc., which constitute a core circuit. The transistors TR may be insulated by an isolation layer 103 formed in the substrate 101. The transistors TR are formed on an active area of the substrate 101 separated by the isolation layer 103. Each of the transistors TR includes a gate insulating layer 107 formed on the active area of the substrate 101, a gate pattern 109 formed on the gate insulating layer 107, and a source/drain area 105 formed in the substrate 101 of both sides of the gate pattern 109.

At least one of the transistors TR may overlap an area in which the memory string ST and the source line 151C are formed. Therefore, according to an embodiment of the present invention, a chip size of the semiconductor device may be reduced by fully using the area of the substrate 101.

At least one of the transistors TR may be connected to the bit line 191 via the page buffer interconnection 151A. At least one of lower interlayer insulating layers 121, 131, and 141 may be formed between the transistors TR and the metal patterns 151A, 151B, and 151C. Furthermore, at least one of contact plugs 123 and 143, and at least one contact interconnection 133 passing through the lower interlayer insulating layers 121, 131, and 141 are formed between the transistors TR and the peripheral circuit interconnections 151A, 151B and 151C. For example, first contact plugs 123 may be formed passing through a first lower interlayer insulating layer 121. The contact interconnections 133 may be connected on the first contact plugs 123 through a second lower interlayer insulating layer 131. Second contact plugs 143 may be connected on the contact interconnections 133 through a third lower interlayer insulating layer 141. One of the first contact plugs 123, one of the contact interconnections 133 and one of the second contact plugs 143 may be formed between the source line 151C and a first transistor among the transistors TR to connect the source line 151C with the first transistor. The first transistor may overlap an area in which the source line 151C is formed. One of the first contact plugs 123, one of the contact interconnections 133 and one of the second contact plugs 143 may be formed between the page buffer interconnection 151A and a second transistor among the transistors TR to connect the page buffer interconnection 151A with the second transistor.

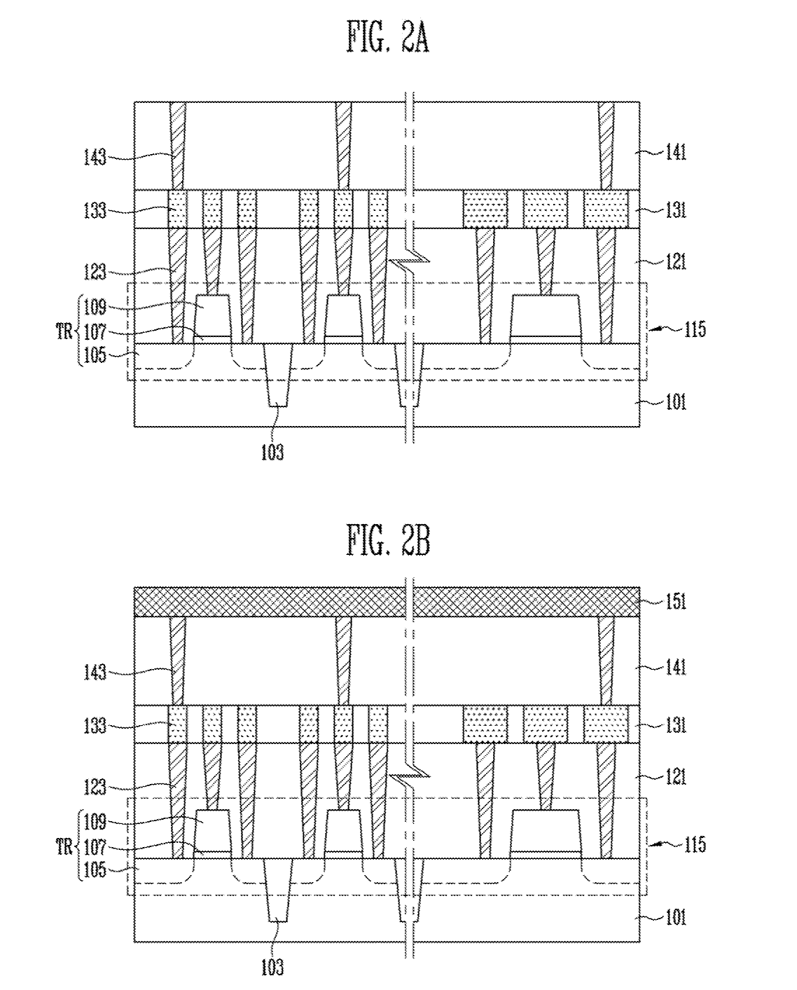

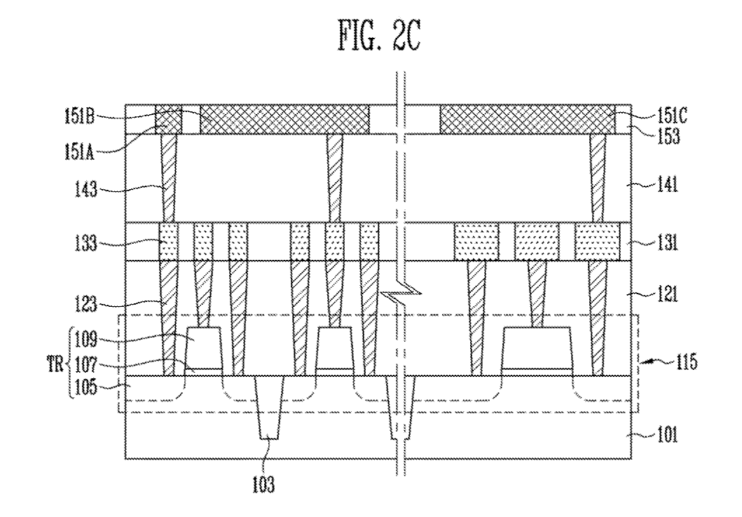

Hereinafter, a method of manufacturing a semiconductor device according to an embodiment of the present invention will be described with reference to FIGS. 2A to 3.

FIGS. 2A to 2C are cross-sectional views illustrating a method of manufacturing a structure formed under a memory string of a semiconductor device according to an embodiment of the present invention.

Referring to FIG. 2A, a gate insulating layer 107 is formed on a substrate 101, and an isolation mask pattern (not shown) is formed on the gate insulating layer 107. Isolation trenches are formed by etching the substrate 101 using an etching process in which the isolation mask pattern is used as an etch mask. Then, isolation layers 103 are formed to fill the isolation trenches with an insulating material. Active areas of the substrate 101 are defined by the isolation layers 103.

After the isolation mask pattern is removed and a conductive layer and a gate mask (not shown) are formed, gate patterns 109 are formed by etching the conductive layer using an etching process in which the gate mask is used as an etch mask. The gate insulating layer 107 may further be etched in the process of etching the conductive layer. The gate mask may be removed after forming the gate patterns 109. Source/drain areas 105 are formed in the substrate 101 of both sides of each of the gate patterns 109 by injecting n-type or p-type impurities. Thus, a peripheral circuit 115 including transistors TR, is formed.

Lower interlayer insulating layers 121, 131, and 141 covering the transistors TR, contact plugs 123 and 143 passing through at least one of the lower interlayer insulating layers 121, 131, and 141, and contact interconnections 133, are formed.

For example, a first lower interlayer insulating layer 121 covering the transistors TR, is formed. After first opening parts are formed by etching the first lower interlayer insulating layer 121, first contact plugs 123 connected to the transistors TR are formed by filling inside the first opening parts with a conductive material. A second lower interlayer insulating layer 131 covering the first contact plugs 123 is formed on the first lower interlayer insulating layer 121. After second opening parts are formed by etching the second lower interlayer insulating layer 131, contact interconnections 133 connected to the first contact plugs 123 are formed by filling inside the second opening parts with a conductive material. A third lower interlayer insulating layer 141 is formed on the second lower interlayer insulating layer 131 on which the contact interconnections 133 are formed. After third opening parts are formed by etching the third lower interlayer insulating layer 141, second contact plugs 143 that are connected to at least one of the contact interconnections 133, are formed by filling inside the third opening parts with a conductive material.

Referring to FIG. 26, a metal layer 151 is formed on the third lower interlayer insulating layer 141. The metal layer 151 may be formed of various conductive materials. For example, the metal layer 151 may be formed of a metal having a lower resistance than silicon, such as tungsten and copper, to reduce a resistance of the source line to be formed in the following process. Another example, the metal layer 151 may be formed of a silicide having a lower resistance than silicon, such as tungsten silicide, to reduce a resistance of the source line to be formed in the following process.

Referring to FIG. 2C, after a mask pattern (not shown) is formed on the metal layer 151, metal patterns 151A, 151B, and 151C are formed by etching the metal layer 151 using an etching process in which the mask pattern is used as an etch mask. Then, the mask pattern is removed.

The metal patterns 151A, 151B, and 151C include peripheral circuit interconnections 151A and 151B, and a source line 151C. Since the peripheral circuit interconnections 151A and 1513, and the source line 151C are simultaneously formed of the same material, according to an embodiment of the present invention, processing costs and processing time may be reduced. The metal patterns 151A, 151B, and 151C are disposed to overlap the transistors TR. The transistors TR, which constitute the peripheral circuit 115, also overlap under the source line 151C.

Then, a cell stacking structure including the memory string, is formed over the metal patterns 151A, 151B, and 151C. Hereinafter, a method of forming a memory string will be described with reference FIG. 3 in detail.

FIG. 3 is a perspective view illustrating a method of manufacturing a memory string of a semiconductor device according to an embodiment of the present invention.

Referring to FIG. 3, a cell stacking structure including a memory strings ST having a 3-dimensional structure is formed over a source line 151C. The cell stacking structure may be formed using various methods.

More specifically, first material layers and second material layers are alternately stacked on an intermediate result in which the source line 151C is formed. The number of stacks of the first material layers and the second material layers may vary. The first material layers are formed on layers on which cell interlayer insulating layers 161 will be formed. The second material layers are formed of a different material from the first material layers, and on layers on which conductive patterns 163, which become word lines and select lines, will be formed.

The first material layers and the second material layers may be formed of various materials. For example, the first material layers may be formed of an insulating material for the cell interlayer insulating layers 161, and the second material layers may be formed of a conductive material for the conductive patterns 163. An oxide layer may be used as an insulating material for the cell interlayer insulating layers 161, and at least one of a poly-silicon layer, a metal silicide layer, and a metal layer may be used as a conductive material for the conductive patterns 163. Alternatively, the first material layers may be formed of an insulating material for the cell interlayer insulating layers 161, and the second material layers may be formed of an insulating material for a sacrificial layer to have an etch selectivity with respect to the first material layers. A nitride layer having an etch selectivity with respect to an oxide layer may be used as an insulating material for the sacrificial layer. Alternatively, the second material layers may be formed of a conductive material for the conductive patterns 163, and the first material layers may be formed of a conductive material for the sacrificial layer to have an etch selectivity with respect to the second material layers. For example, the second material layers may be formed of a doped poly-silicon layer, and the first material layers may be formed of an undoped poly-silicon layer.

After the first material layers and the second material layers are formed, a step structure is formed by etching the first material layers and the second material layers. Before or after the step structure is formed, a channel layer 165 connected to the source line 151C may be formed through the first material layers and the second material layers. After a through hole passing through the first material layers and the second material layers is formed, the channel layer 165 is formed inside the through hole. A plurality of through holes are formed. The plurality of through holes may be arranged in a matrix shape or in a zigzag shape, to be alternately disposed from each other. The channel layer 165 may be formed in a tube shape in which a central area of the through hole is opened along a side all of the through hole, or be filled from a surface of the through hole to the central area of the through hole. When the channel layer 165 is formed in a tube shape, an opened central area of the channel layer 165 may be filled with an insulating material. The channel layer 165 may be formed of a semiconductor layer.

Before the channel layer 165 is formed, a multilayered insulating layer (not shown) including at least one of a tunnel insulating layer (not shown), a data storage layer (not shown), and a blocking insulating layer (not shown) may be formed along the side all of the through hole. The tunnel insulating layer may be formed of a silicon-oxide layer, the data storage layer may be formed of a nitride, layer capable of trapping charge, the blocking insulating layer may be formed of a silicon-oxide layer capable of blocking charge or a high-k dielectric layer of which permittivity is higher than that of a silicon-oxide layer.

A slit (not shown) passing through the first material layers and the second material layers is formed by etching the first material layers and the second material layers penetrated by the channel layer 165 and patterned in a step shape. The slits may have various shapes. The number of slits may vary. The slits may be formed in various areas.

When the first material layers are formed of an insulating material for the cell interlayer insulating layers 161 and the second material layers are formed of a conductive material for the conductive patterns 163, the cell interlayer insulating layers 161 and the conductive patterns 163 may be divided by the slit into units of memory blocks or into units of memory strings.

When the first material layers are formed of an insulating material for the cell interlayer insulating layers 161 and the second material layers are formed of an insulating material for a sacrificial layer to have an etch selectivity with respect to the first material layers, opening parts are formed by selectively removing the second material layers exposed by the slit. Then, the conductive patterns 163 are formed by filling the opening parts with a conductive material.

When the second material layers are formed of a conductive material for the conductive patterns 163 and the first material layers are formed of a conductive material for the sacrificial layer, the opening parts are formed by selectively removing the first material layers exposed by the slit. Then, the cell interlayer insulating layers 161 are formed by filling the opening parts with an insulating material.

As the cell interlayer insulating layers 161 and the conductive patterns 163, which are penetrated by the channel layer 165 and are alternately stacked, are formed through the above-described various processes, a memory string ST including memory cells stacked in 3-dimensions along the channel layer 165 may be formed. At least one layer from the lowermost layer adjacent to the source line 151C of the conductive patterns 163 may be used as a first select line, at least one layer from the uppermost layer thereof may be used as a second select line, and others may be used as word lines. Thus, the memory string ST is configured of at least one the first select transistor, the memory cells, and at least one the second select transistor, which are connected in series.

After the above-described memory string ST is formed, an upper interlayer insulating layer 173 shown in FIG. 1 may be formed. After the upper interlayer insulating layer 173 is formed, a surface of the upper interlayer insulating layer 173 may be planarized. A drain contact hole configured to open the channel layer 165 is formed through the upper interlayer insulating layer 173, and a drain contact plug 183 may be formed by filling inside the drain contact hole with a conductive material. A bit line contact hole configured to open at least one of peripheral circuit interconnections 151A and 151B (for example, a page buffer interconnection 151A), may be formed through the upper interlayer insulating layer 173, and a bit line contact plug 185 may be formed by filling inside the bit line contact hole with a conductive material.

Subsequently, as shown in FIG. 1, a bit line 191 may be formed. The bit line 191 is connected to the bit line contact plug 185 and the drain contact plug 183.

According to the present invention as described above, since the peripheral circuit interconnections 151A and 151B and the source line 151C are simultaneously formed, processing costs and processing time may be reduced.

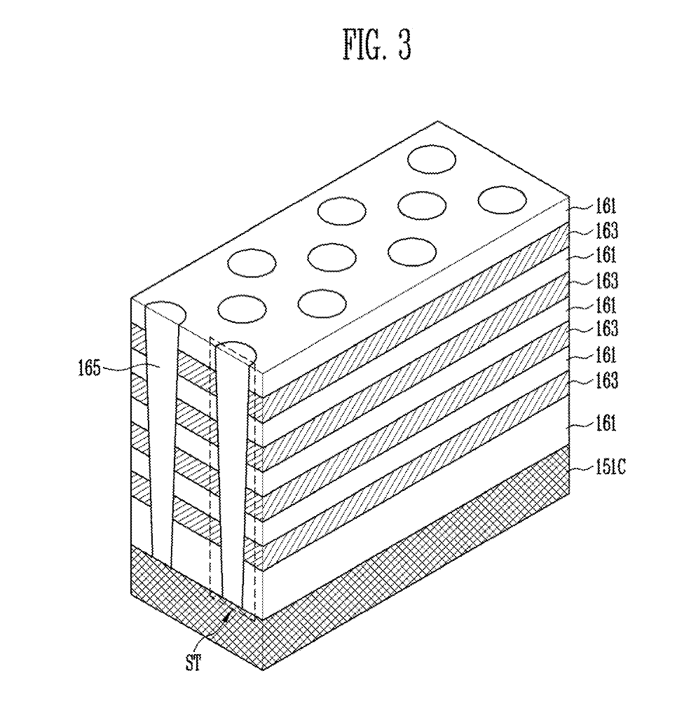

FIG. 4 is a block diagram illustrating a memory system according to an embodiment of the present invention.

Referring to FIG. 4, a memory system 1100 according to an embodiment of the present invention includes a memory device 1120 and a memory controller 1110.

The memory device 1120 has a structure described in embodiments of FIGS. 1 to 3. The memory device 1120 may be a multi-chip package configured of a plurality of lash memory chips.

The memory controller 1110 is configured to control the memory device 1120 and may include a static random access memory (SRAM) 1111, a central processing unit (CPU) 1112, a host interface 1113, an error correction code (ECC) 1114, and a memory interface 1115. The SRAM 1111 is used as an operation memory of the CPU 1112. The CPU 1112 is configured to perform overall control operations for exchanging data of the memory controller 1110. The host interface 1113 has a data exchanging protocol of the host connected to the memory system 1100. The ECC 1114 is configured to detect and correct errors in data read from the memory device 1120, and the memory interface 1115 is configured to perform interfacing with the memory device 1120. In addition, the memory controller 1110 may further include a read only memory (ROM) to store code data for interfacing with the host.

The memory system 1100 having such a configuration may be a memory card or a solid-state disk (SSD) in which the memory device 1120 and the memory controller 1110 are combined. For example, when the memory system 1100 is an SSD, the memory controller 1110 may communicate with the outside (for example, a host) through one of various interface protocols, such as Universal Serial Bus (USB), MultiMediaCard (MMC), Peripheral Component Interconnect-Express (PCI-E), Serial-Advanced Technology Attachment (SATA), Parallel-Advanced Technology Attachment (PATH), Small Computer System Interface (SCSI), Enhanced Small Disk Interface (ESDI), Integrated Drive Electronics (IDE), and so on.

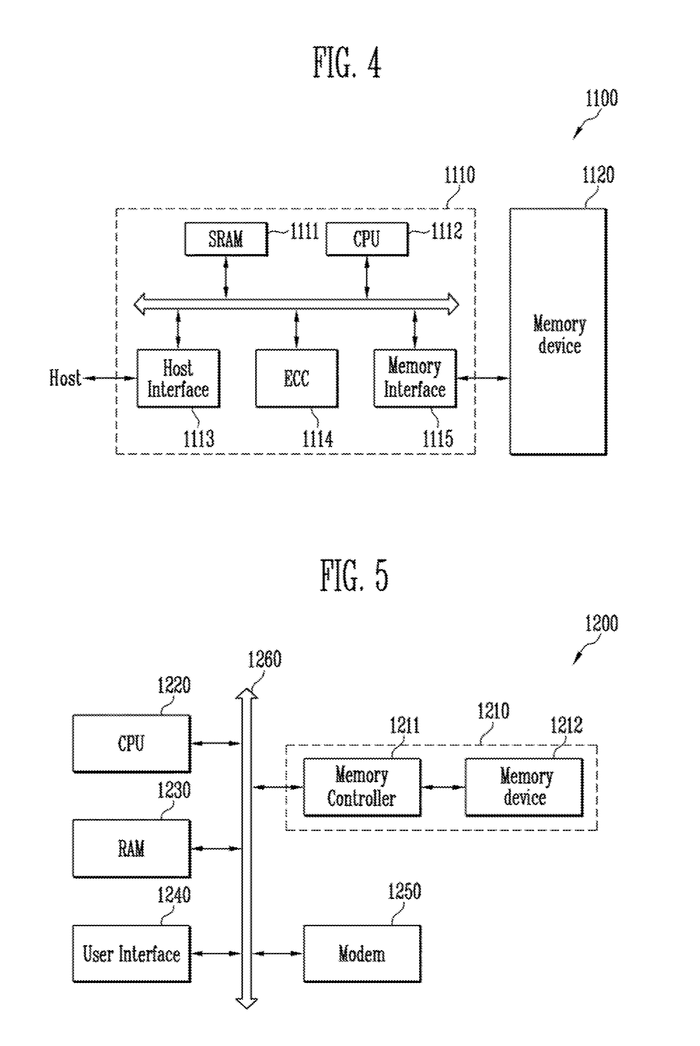

FIG. 5 is a block diagram illustrating a computing system according to the embodiment of the present invention.

Referring to FIG. 5, a computing system 1200 according to the embodiment of the present invention may include a CPU 1220, a random access memory (RAM) 1230, a user interface 1240, a modern 1250, and a memory system 1210, which are electrically connected to a system bus 1260. When the computing system 1200 is a mobile device, the computing system 1200 may further include a battery for supplying an operating voltage and may further include an application chipset, a camera image processor (CIS), a mobile dynamic random access memory (DRAM), and so on.

As described above with reference to FIG. 4, the memory system 1210 may include a memory device 1212 and a memory controller 1211.

According to an embodiment of the present invention, as some of the metal patterns are used as a source line connected to the memory string, a resistance of the source line may be reduced.

According to the present invention, as the source line connected to the memory string and the peripheral circuit interconnection connected to the transistors that constitute the peripheral circuit, are simultaneously formed, processing costs and processing time may be reduced.

In the drawings and specification, there have been disclosed typical exemplary embodiments of the invention, and although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A semiconductor device, comprising:
a memory string;
a first metal pattern for a source line formed under the memory string;
a second metal pattern for a peripheral circuit interconnection horizontally spaced apart from the first metal pattern; and
peripheral circuit transistors connected to the second metal pattern.

2. The semiconductor device of claim 1, further comprising:
a bit line connected to the memory string; and
a contact plug connected between the second metal pattern and the bit line.

3. The semiconductor device of claim 1, further comprising at least one contact plug and at least one contact interconnection, which are formed between the second metal pattern and the transistor.

4. The semiconductor device of claim wherein the memory string includes:
cell interlayer insulating layers and conductive patterns which are alternately stacked on the first metal pattern; and
a channel layer connected to the first metal pattern through the cell interlayer insulating layers and the conductive patterns.

5. The semiconductor device of claim 1, wherein the first metal pattern overlaps a first transistor among the transistors.

6. The semiconductor device of claim 5, further comprising at least one contact plug and at least one contact interconnection, which are formed between the first metal pattern and the first transistor.

7. The semiconductor device of claim 1, wherein the first metal pattern and the second metal pattern are formed of a metal or a silicide having a lower resistance than silicon.

8. The semiconductor device of claim 1, wherein the first metal pattern is divided into units of the memory strings or into units of memory blocks.

9. The semiconductor device of claim 1, wherein the first metal pattern connected to a plurality of memory blocks.

10. A semiconductor device, comprising:
peripheral circuit transistors formed on a substrate;
metal patterns disposed over the peripheral circuit transistors in a same level; and
a memory string formed over the metal patterns,
wherein the metal patterns include peripheral circuit interconnections connected to the peripheral circuit transistors and a source line connected to the memory string.

11. A semiconductor device, comprising:
a bit line;
an interconnection line and a source line disposed under the bit line, wherein a distance between the interconnection line and the bit line is the same a distance between the source line and the bit line;
a memory string connected between the bit line and the source line;
a page buffer circuit disposed under the interconnection line;
a first contact plug connected between the page buffer circuit and the interconnection line; and
a second contact plug connected between the interconnection line and the bit line.

12. The semiconductor device of claim 11, wherein the memory string includes:
cell interlayer insulating layers and conductive patterns, which are alternately stacked between the source line and the bit line; and
a channel layer connected between the source line and the bit line through the cell interlayer insulating layers and the conductive patterns.

13. The semiconductor device of claim 11, wherein the source line and the interconnection line are formed of the same material.

14. The semiconductor device of claim 11, wherein the source line and the interconnection line are formed of a metal or a silicide having a lower resistance than silicon.

15. A method of manufacturing a semiconductor device, comprising:
forming transistors on a substrate;
forming at least one lower interlayer insulating layer to cover the transistors;
forming a metal layer on the lower interlayer insulating layer;
forming a first metal pattern for a source line and a second metal pattern for a peripheral circuit interconnection by etching the metal layer; and
forming a memory string connected to the first metal pattern.

16. The method of claim 15, wherein the forming of the memory string includes:
alternately stacking first material layers and second material layers on the first metal pattern; and
forming a channel layer connected to the first metal pattern through the first material layers and the second material layers.

17. The method of claim 16, further comprising: after forming the channel layer,
forming a contact plug connected to the second metal pattern; and
forming a bit line connected to the contact plug and the channel layer.

18. The method of claim 15, further comprising before forming the metal layer,
forming contact plugs connected to the transistors through the lower interlayer insulating layer, and contact interconnections connected to the contact plugs.

19. The method of claim 15, wherein the memory string and the first metal pattern are formed to overlap the transistors.
